(19) United States
(12) Patent Application Publication
(10) Pub. No.: US 2004/0192066 A1
(43) Pub. Date: Sep. 30, 2004

(54) Method for immersing a substrate

(75) Inventors: Dmitry Lubomirsky, Cupertino, CA (US); Michael X. Yang, Palo Alto, CA (US)

Correspondence Address: PATENT COUNSEL, APPLIED MATERIALS, INC., Legal Affairs Department, P.O. Box 450A, Santa Clara, CA, 95052, US

(73) Assignee: Applied Materials, Inc.

(21) Appl. No.: 10/781,040

(22) Filed: Feb. 18, 2004

Related U.S. Application Data
(60) Provisional application No. 60/448,575, filed on Feb. 18, 2003.

(51) Int. Cl. H01L 21/31

(52) U.S. Cl. 438/758; 438/782

(57) ABSTRACT

Embodiments of the invention generally provide a method for immersing a substrate into a fluid solution. The method includes loading a substrate into a receiving member configured to support the substrate in a face down orientation, tilting the receiving member to a first tilt angle measured from horizontal, displacing the receiving member toward the fluid solution, and tilting the receiving member to a second tilt angle measured from horizontal during the displacing.

### CROSS-REFERENCE TO RELATED APPLICATIONS

This application claims benefit of U.S. provisional patent application 60/448,575, filed Feb. 18, 2003, which is herein incorporated by reference.

### BACKGROUND OF THE INVENTION

1. Field of the Invention

Embodiments of the invention generally relate to a method for immersing a semiconductor substrate into a processing fluid.

2. Description of the Related Art

Metallization of sub-quarter micron sized features is a foundational technology for present and future generations of integrated circuit manufacturing processes. More particularly, in devices such as ultra large scale integration-type devices, i.e., devices having integrated circuits with more than a million logic gates, the multilevel interconnects that lie at the heart of these devices are generally formed by filling high aspect ratio, i.e., greater than about 4:1, interconnect features with a conductive material, such as copper. Conventionally, deposition techniques such as chemical vapor deposition (CVD) and physical vapor deposition (PVD) have been used to fill these interconnect features. However, as the interconnect sizes decrease and aspect ratios increase, void-free interconnect feature fill via conventional metallization techniques becomes increasingly difficult. Therefore, plating techniques, i.e., electrochemical plating (ECP) and electroless plating, have emerged as promising processes for void free filling of sub-quarter micron sized high aspect ratio interconnect features in integrated circuit manufacturing processes.

In an ECP process, for example, sub-quarter micron sized high aspect ratio features formed into the surface of a substrate (or a layer deposited thereon) may be efficiently filled with a conductive material. ECP plating processes are generally two stage processes, wherein a seed layer is first formed over the surface features of the substrate (generally through PVD, CVD, or other deposition process in a separate tool), and then the surface features of the substrate are exposed to an electrolyte solution (in the ECP tool), while an electrical bias is applied between the seed layer and a copper anode positioned within the electrolyte solution. The electrolyte solution generally contains a source of metal that is be plated onto the surface of the substrate, and therefore, the application of the electrical bias causes the metal source to be plated onto the biased seed layer, thus depositing a layer of the ions on the substrate surface that may fill the features.

However, the decreasing size of features being filled by ECP processes in semiconductor processing requires that the plating process generate minimal defects in order to produce viable devices. Research has shown that a primary cause of plating defects is the presence of air bubbles on the surface of the substrate being plated. Generally, air bubbles are formed on the surface of the substrate during the process of immersing the substrate into the plating solution. More particularly, as the substrate is transitioned from the air into the plating solution, small bubbles often adhere to the surface of the substrate. These air bubbles prevent the electrolyte solution from contacting the substrate surface at that particular location, and therefore, prevent plating at that location, which in turn forms a defect in the plated layer. Bubbles adhering to the substrate surface during immersion may also dislodge and travel across the. surface of the substrate once the substrate is immersed in the plating solution, which may generate multiple defects in multiple locations along the bubble path.

Conventional immersion schemes have attempted to address this issue by attaching the substrate to a lid-type member that is pivotally attached to a location next to the processing solution the substrate is to be immersed into, such that the lid may be pivoted to essentially cover the processing solution while immersing the substrate therein. The lid is then pivoted downward toward the processing solution to immerse the substrate. However, these schemes include two disadvantages. First, rotation of the substrate in the lid-type configuration was not easily implemented, and as such, bubble adherence was not substantially reduced. Second, the angular immersion that results from the lid-type apparatuses also has not shown acceptable bubble related defect reduction ratios.

Therefore, there is a need for a method for immersing a substrate into an electrolyte solution, wherein the immersion method is configured to minimize bubble formation on the surface of the substrate during the immersion process.

### SUMMARY OF THE INVENTION

Embodiments of the invention generally provide a method for immersing a substrate into an electrolyte solution with minimal bubble formation. The method generally includes tilting the substrate to a tilt angle from horizontal and immersing (actuating in the Z-direction) the substrate into the plating solution. Once the substrate is immersed, the substrate is tilted back to a horizontal position within the plating solution. Thereafter, the substrate is again actuated in the Z-direction downward in the plating solution toward the anode of the plating cell. The substrate is then tilted to a tilt angle from horizontal and actuated in the Z-direction to a processing position, wherein the processing position corresponds to positioning the substrate in parallel orientation to the upper surface of the anode.

Embodiments of the invention may further provide a method for immersing a substrate into a fluid solution. The method generally includes loading a substrate into a receiving member configured to support the substrate in a face down orientation, tilting the receiving member to a first tilt angle measured from horizontal, displacing the receiving member toward the fluid solution, and tilting the receiving member to a second tilt angle measured from horizontal during the displacing.

Embodiments of the invention may further provide a method for minimizing bubble adherence during a substrate immersion process. The method generally includes tilting the substrate to a tilt angle measured from horizontal, vertically actuating the substrate toward a fluid solution, reducing the tilt angle to about horizontal once the substrate contacts the fluid solution, while continuing the vertical actuation of the substrate, and positioning the substrate at a processing angle.

Embodiments of the invention may further provide method for immersing a substrate into a plating electrolyte. The method generally includes positioning the substrate on a contact ring, securing the substrate to the contact ring with a thrust plate assembly, tilting the contact ring to a tilt angle of between about 3° and about 7°, vertically actuating the contact ring toward the plating electrolyte while maintaining the tilt angle, rotating the contact ring at a rotation rate of between about 30 rpm and about 120 rpm, reducing the tilt angle to about horizontal when the contact ring initially touches the plating electrolyte, and positioning the substrate in a processing position.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top plan view of one embodiment of an electrochemical plating system of the invention.

FIG. 2 illustrates a partial perspective and sectional view of an exemplary plating cell used in the plating system of the invention.

FIG. 3 illustrates a sectional view of a plating cell and head assembly during a substrate transfer process.

FIG. 4 illustrates a sectional view of a plating cell and head assembly during a tilting process.

FIG. 5 illustrates a sectional view of a plating cell and head assembly during an immersion process, i.e., during vertical actuation.

FIG. 6 illustrates a sectional view of a plating cell and head assembly during a tilting process after immersion.

FIG. 7 illustrates a sectional view of a plating cell and head assembly during an immersion process wherein the head assembly is positioning the substrate deeper in the plating solution.

FIG. 8 illustrates a sectional view of a plating cell and head assembly positioned in a processing position.

FIG. 9 illustrates a flowchart of the immersion method of the invention.

### DETAILED DESCRIPTION OF THE PREFERRED EMBODIMENT

Embodiments of the invention generally provide a method for immersing a substrate into an electrochemical plating solution. The immersion method of the invention is configured to minimize plating defects by minimizing bubble formation and adhesion to the substrate surface during the immersion process. The immersion method of the invention generally includes driving or actuating the substrate into the plating solution using a combination of a tilt and swing immersion processes. More particularly, the substrate may be tilted at an angle with respect to horizontal, and then vertically actuated toward the plating solution, while being rotated, which immerses the substrate and maintains a constant angle between the substrate and the upper surface of the plating solution. The combination of the tilt and rotation causes bubbles to be dislodged from the substrate surface and carried away from the substrate surface as a result of the buoyancy of the bubbles. Further, the tilt angle of the substrate may be adjusted during the immersion process, thus generating a swing or pendulum type motion, which also urges bubbles attached to the substrate surface to be dislodged therefrom.

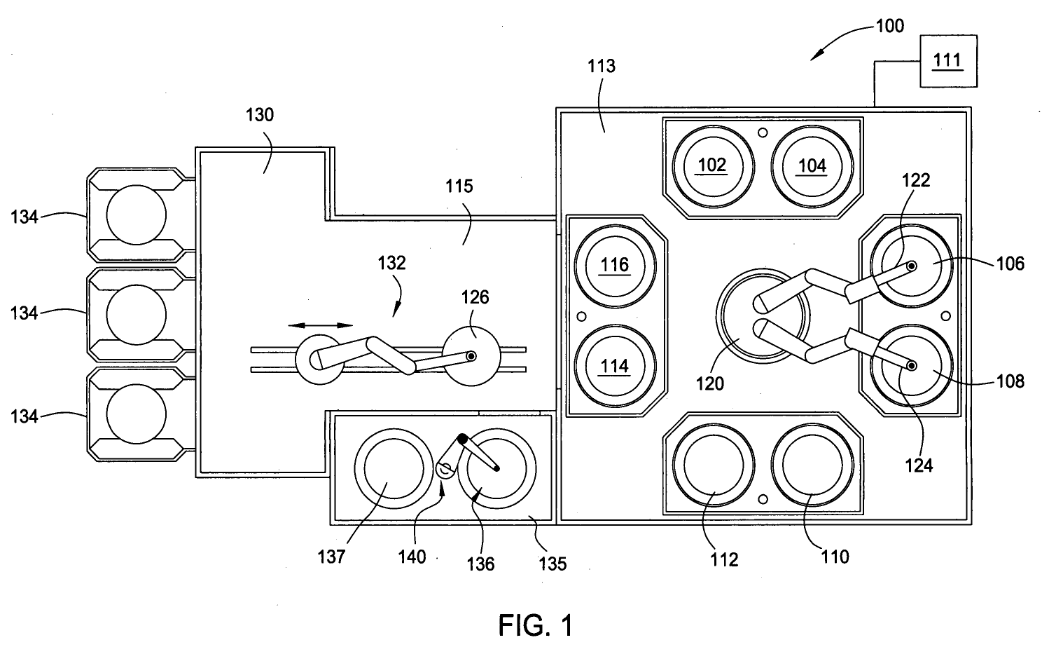

FIG. 1 illustrates a top plan view of an ECP system 100 of the invention. ECP system 100 includes a factory interface (Fl) 130, which is also generally termed a substrate loading station. Factory interface 130 includes a plurality of substrate loading stations configured to interface with substrate containing cassettes 134. A robot 132 is positioned in factory interface 130 and is configured to access substrates contained in the cassettes 134. Further, robot 132 also extends into a link tunnel 115 that connects factory interface 130 to processing mainframe or platform 113. The position of robot 132 allows the robot to access substrate cassettes 134 to retrieve substrates therefrom and then deliver the substrates to one of the processing cells 114, 116 positioned on the mainframe 113, or alternatively, to the annealing station 135. Similarly, robot 132 may be used to retrieve substrates from the processing cells 114, 116 or the annealing chamber 135 after a substrate processing sequence is complete. In this situation robot 132 may deliver the substrate back to one of the cassettes 134 for removal from system 100.

The anneal chamber 135 generally includes a two position annealing chamber, wherein a cooling plate/position 136 and a heating plate/position 137 are positioned adjacently with a substrate transfer robot 140 positioned proximate thereto, e.g., between the two stations. The robot 140 is generally configured to move substrates between the respective heating 137 and cooling plates 136. Further, although the anneal chamber 135 is illustrated as being positioned such that it is accessed from the link tunnel 115, embodiments of the invention are not limited to any particular configuration or placement. As such, the anneal chamber may be positioned in communication with the mainframe 113.

As mentioned above, ECP system 100 also includes a processing mainframe 113 having a substrate transfer robot 120 centrally positioned thereon. Robot 120 generally includes one or more arms/blades 122, 124 configured to support and transfer substrates thereon. Additionally, the robot 120 and the accompanying blades 122, 124 are generally configured to extend, rotate, and vertically move so that the robot 120 may insert and remove substrates to and from a plurality of processing stations 102, 104, 106, 108, 110, 112, 114, 116 positioned on the mainframe 113. Similarly, factory interface robot 132 also includes the ability to rotate, extend, and vertically move its substrate support blade, while also allowing for linear travel along the robot track that extends from the factory interface 130 to the mainframe 113. Generally, process stations 102, 104, 106, 108, 110, 112, 114, 116 may be any number of processing cells utilized in an electrochemical plating platform. More particularly, the process locations may be configured as electrochemical plating cells, rinsing cells, bevel clean cells, spin rinse dry cells, substrate surface cleaning cells, electroless plating cells, metrology inspection stations, and/or other processing cells that may be beneficially used in conjunction with a plating platform. Each of the respective processing cells and robots are generally in communication with a process controller 111, which may be a microprocessor-based control system configured to receive inputs from both a user and/or various sensors positioned on the system 100 and appropriately control the operation of system 100 in accordance with the inputs.

In the exemplary plating system illustrated in FIG. 1, the processing stations may be configured as follows. Processing stations 114 and 116 may be configured as an interface between the wet processing stations on the mainframe 113 and the dry processing regions in the link tunnel 115, annealing chamber 135, and the factory interface 130. The processing cells located at the interface locations may be spin rinse dry cells and/or substrate cleaning cells. More particularly, each of stations 114 and 116 may include both a spin rinse dry cell and a substrate cleaning cell in a stacked configuration. Stations 102, 104, 110, and 112 may be configured as plating cells, either electrochemical plating cells or electroless plating cells, for example. Stations 106, 108 may be configured as substrate bevel cleaning cells. Additional configurations and implementations of an electrochemical processing system are illustrated in commonly assigned U.S. patent application Ser. No. 10/435,121 filed on Dec. 19, 2002 entitled “Multi-Chemistry Electrochemical Processing System”, which is incorporated herein by reference in its entirety.

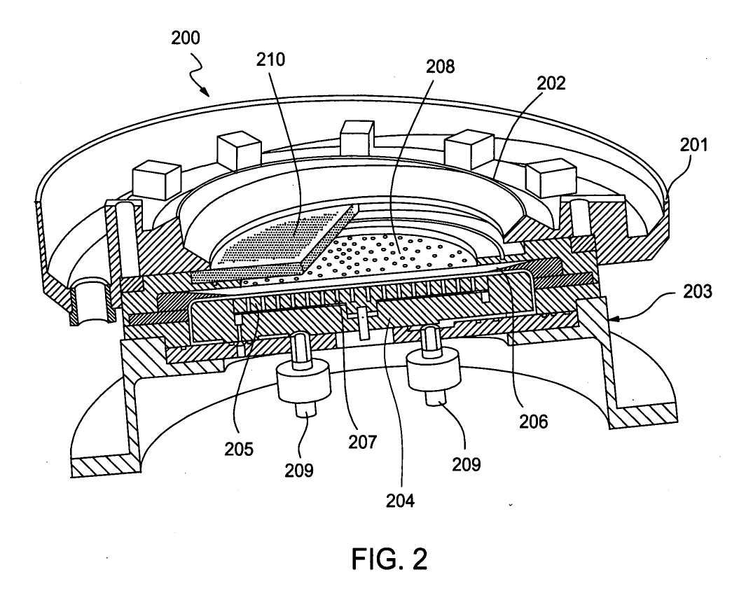

FIG. 2 illustrates a partial perspective and sectional view of an exemplary plating cell 200 that may be implemented in processing stations 102, 104, 110, and 112. The electrochemical plating cell 200 generally includes an outer basin 201 and an inner basin 202 positioned within outer basin 201. Inner basin 202 is generally configured to contain a plating solution that is used to plate a metal, e.g., copper, onto a substrate during an electrochemical plating process. During the plating process, the plating solution is generally continuously supplied to inner basin 202, and therefore, the plating solution continually overflows the uppermost point (generally termed a “weir”) of inner basin 202 and is collected by outer basin 201 and drained therefrom for chemical management and recirculation. Plating cell 200 is generally positioned at a tilt angle, i.e., the frame portion 203 of plating cell 200 is generally elevated on one side such that the components of plating cell 200 are tilted between about.3⁰ and about 30°, or generally between about 4° and about 10° for optimal results. The frame member 203 of plating cell 200 supports an annular base member on an upper portion thereof. Since frame member 203 is elevated on one side, the upper generally planar surface of base member 204 is generally tilted from the horizontal at an angle that corresponds to the tilt angle of frame member 203 relative to a horizontal position. Base member 204 includes an annular or disk shaped recess formed into a central portion thereof, the annular recess being configured to receive a disk shaped anode member 205. Base member 204 further includes a plurality of fluid inlets/drains 209 extending from a lower surface thereof. Each of the fluid inlets/drains 209 are generally configured to individually supply or drain a fluid to or from either the anode compartment or the cathode compartment of plating cell 200. Anode member 205 generally includes a plurality of slots 207 formed therethrough, wherein the slots 207 are generally positioned in parallel orientation with each other across the surface of the anode 205. The parallel orientation allows for dense fluids generated at the anode surface to flow downwardly across the anode surface and into one of the slots 207. Plating cell 200 further includes a membrane support assembly 206. Membrane support assembly 206 is generally secured at an outer periphery thereof to base member 204, and includes an interior region configured to allow fluids to pass therethrough. A membrane 208, which is generally an ionic membrane configured to selectively allow transmission of ions therethrough, is stretched across a lower surface of the support 206 and operates to fluidly separate a catholyte chamber and anolyte chamber portions of the plating cell. Embodiments of the invention generally utilize a cationic membrane that is configured to allow positive copper ions to travel therethrough in the direction of the substrate, while preventing constituents (predominantly the organic additives) of the plating solution from traveling through the membrane 208 in the direction of the anode 205. The membrane support assembly 206 may include an o-ring type seal positioned near a perimeter of the membrane, wherein the seal is configured to prevent fluids from traveling from one side of the membrane 208 secured on the membrane support 206 to the other side of the membrane 208.

A diffusion plate 210, which is generally a porous ceramic disk member is configured to generate a substantially laminar flow or even flow of fluid in the direction of the substrate being plated, may optionally be positioned in the cell between membrane 208 and the substrate being plated. The exemplary plating cell and the above noted components are further illustrated in commonly assigned U.S. patent application Ser. No. 10/268,284, which was filed on Oct. 9, 2002 under the title “Electrochemical Processing Cell”, claiming priority to U.S. Provisional Application Serial No. 60/398,345, which was filed on Jul. 24, 2002, both of which are incorporated herein by reference in their entireties to the extent that these applications are not inconsistent with the present invention.

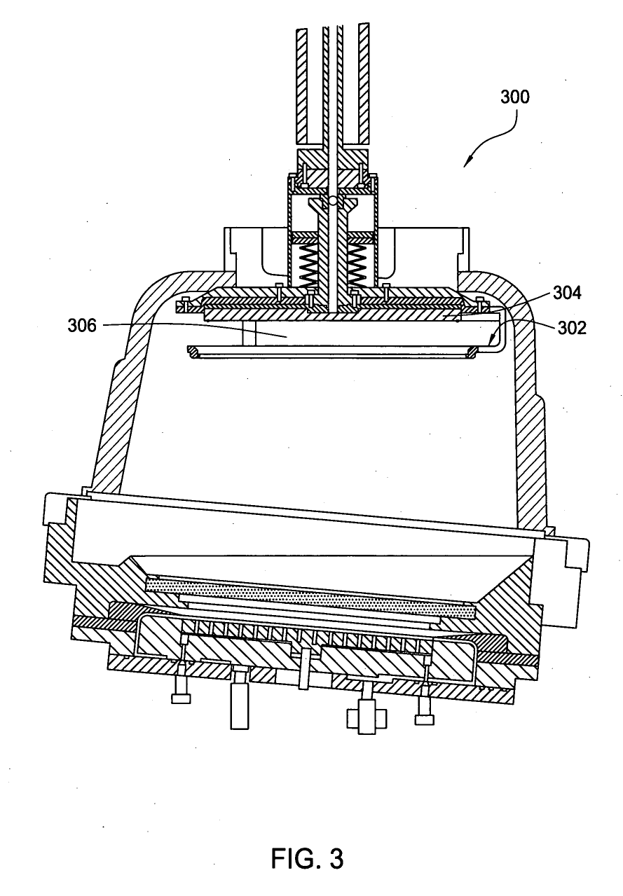

As noted above, in order to minimize defects in plated films, bubbles adhering to the substrate surface during the process of immersing the substrate into the plating solution contained in a plating cell should be minimized. AN example of an apparatus and method for immersing a substrate that is configured to minimize bubble formation is illustrated in commonly assigned U.S. patent application Ser. No. 10/266,477, entitled “Tilted Electrochemical Plating Cell with Constant Wafer Immersion Angle” and filed on Oct. 7, 2002, which is hereby incorporated by reference in its entirety to the extent no inconsistent with the present invention. Embodiments of the invention provide an improved method for immersing a substrate into a processing fluid that generates minimal bubble adherence to the substrate surface. The immersion method of the invention begins with the process of loading a substrate into a head assembly 300, as illustrated in FIG. 3. The head assembly 300 generally includes a contact ring 302 and a thrust plate assembly 304 that are separated by a loading space 306. A more detailed description of the contact ring 302 and thrust plate assembly 304 may be found in commonly assigned U.S. patent application Ser. No. 10/278,527, which was filed on Oct. 22, 2002 under the title “Plating Uniformity Control By Contact Ring Shaping”, and commonly assigned U.S. Pat. No. 6,251,236 entitled Cathode Contact Ring for Electrochemical Deposition, both of which are hereby incorporated by reference in their entirety to the extent not inconsistent with the present invention.

A robot, such as robot 120 illustrated in FIG. 1, is used to position a substrate on the contact ring 302 via access space 306. More particularly, robot 120 may be a vacuum-type robot configured to engage a backside of the substrate with a reduced pressure engaging device. The substrate may then be. supported in a face down (production surface facing down) orientation with the vacuum engaging device attached to the backside or non-production surface of the substrate. The robot may then extend into contact ring 302 via access space 306, lower to position the substrate on the contact pins/substrate support surface of contact ring 302, disengage the vacuum engaging device, raise to a withdrawal height, and then withdraw from the contact ring 302 leaving the substrate supported by the contact ring 302.

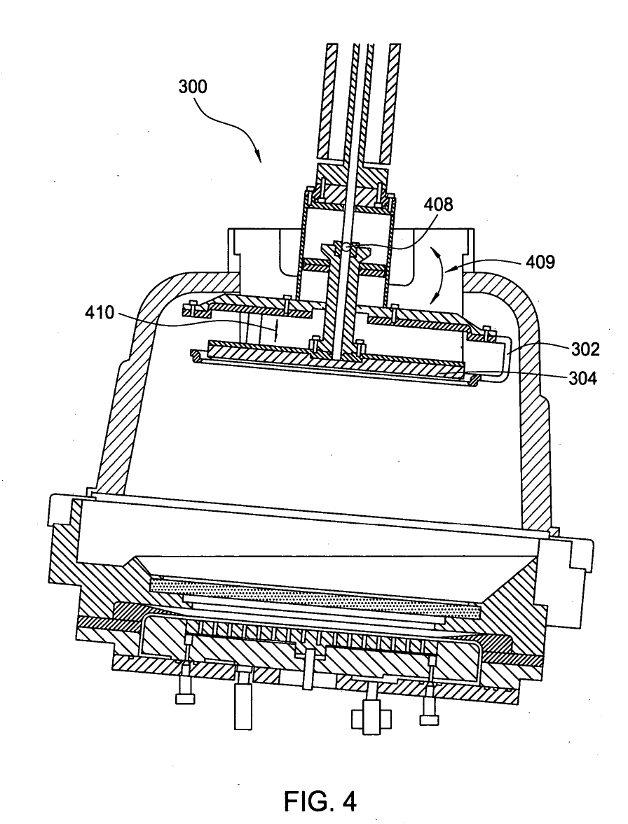

Once the substrate is positioned on the contact ring 302, thrust plate assembly 304 may be lowered into a processing position. More particularly, FIG. 3 illustrates thrust plate 304 in a substrate loading position, i.e., thrust plate 304 is vertically positioned above the lower surface of contact ring 302 such that the access space 306 is maximized. In this position, robot 120 has the most amount of space available to loading the substrate onto the contact ring 302. However, once the substrate is loaded, thrust plate 304 may be actuated vertically, i.e., in the direction indicated by arrow 410 in FIG. 4, to engage the backside of the substrate positioned on the contact ring 302. The engagement of the thrust plate 304 with the backside of the substrate positioned on the contact ring 302 operates to mechanically bias the substrate against the electrical contact pins positioned on contact ring 302, while also securing the substrate to the contact ring 302 for processing. The engagement of the thrust plate 304 with the backside of the substrate also may operate to create a fluid seal between the substrate and the thrust plate 304, as the thrust plate 304 may include an o-ring or other type of fluid seal positioned thereon. This seal, when engaged with the backside of the substrate, generally operates to create a fluid barrier between the thrust plate 304 and the substrate that prevents processing fluids from contacting the backside of the substrate.

Once the substrate is secured to the contact ring 302 by the thrust plate 304, the lower portion of the head assembly 300, i.e., the combination of the contact ring 302 and the thrust plate 304, may be positioned at a tilt angle. The lower portion of the head assembly is pivoted to the tilt angle via pivotal actuation of the head assembly about a pivot point 408. The lower portion of head assembly 300 is actuated about pivot point 408, which causes pivotal movement of the lower portion of head assembly 300 in the direction indicated by arrow 409 in FIG. 4. The lower portion of head assembly 300 and the plating surface of the substrate positioned on the contact ring 302 are tilted to the tilt angle as a result of the movement of head assembly 300, wherein the tilt angle is defined as the angle between horizontal and the plating surface/production surface of the substrate secured to the contact ring 302. The tilt angle is generally between about 3° and about 30°, and more particularly, between about 3° and about 10°. Further, pivot point 408 is generally positioned such that when the head assembly is tilted, a central vertical axis of the substrate remains in substantially the same location as when the substrate was positioned horizontally, i.e., the pivot point 408 is generally positioned proximate contact ring 302.

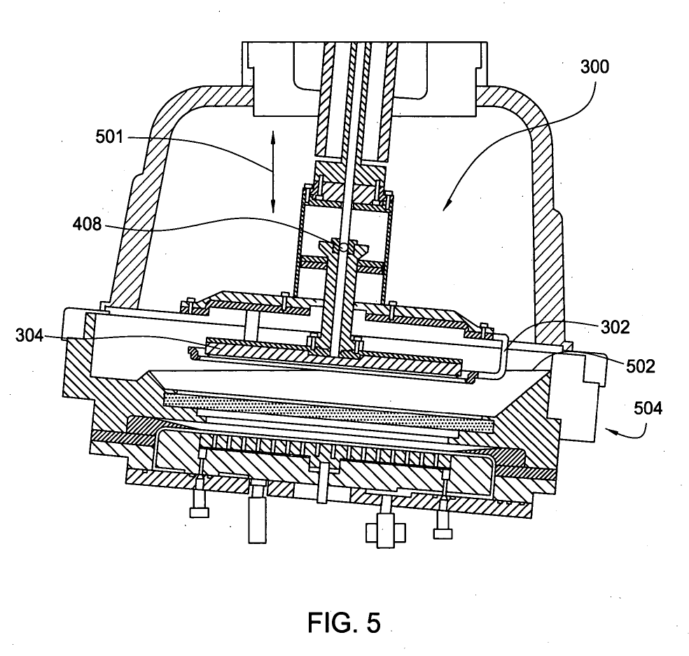

Once the head assembly 300 is tilted, it may be actuated in the Z-direction to begin the immersion process, although the invention is not intended to be limited to this sequence, as the Z actuation and the tilting process may be conducted simultaneously or in another sequence. In the current embodiment of the invention, head assembly 300 is actuated in the direction indicated by arrow 501, as illustrated in FIG. 5, to bring the substrate positioned in the contact ring 302 toward the plating solution contained within the plating cell 504 positioned below head assembly 300. The direction indicated by arrow 501 may be parallel to the central axis of the substrate, or alternatively, the direction indicated by arrow 501 may be substantially vertical.

Plating cell 504, which is generally similar to plating cell 200 illustrated in FIG. 2, contains a plating solution. The plating solution generally overflows the uppermost point 502 of the inner weir, and as such, the upper surface of the plating solution bath forms a substantially planar fluid surface. Therefore, as head assembly 300 is moved toward plating cell 504, the lower side of contact ring 302, i.e., the side of contact ring 302 positioned closest plating cell 504 as a result of the tilt angle, contacts the plating solution as the head assembly 300 is actuated toward cell 502. The process of actuating head assembly 300 toward cell 502 may further include imparting rotational movement to contact ring 302. The rotational movement may be between about 10 rpm and about 240 rpm, or more particularly, between about 60 rpm and about 120 rpm, for example. Thus, during the initial stages of the immersion process, contact ring. 302 is being actuated in a vertical or Z-direction, while also being rotated about a central axis that intersects the radial center of the substrate, which is also generally orthogonal to the substrate surface.

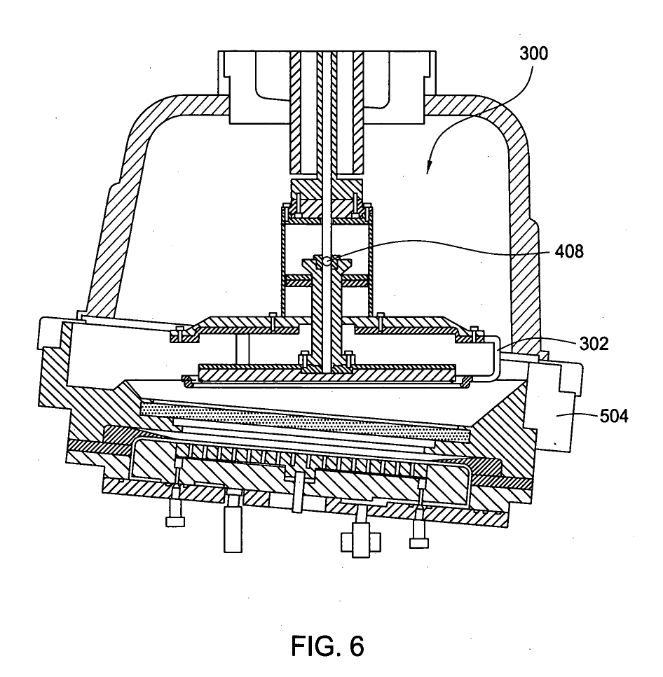

As the substrate becomes immersed in the plating solution contained within plating cell 504, the Z-motion of head assembly 300 may be slowed and/or terminated and the tilt position of contact ring 302 is returned to horizontal, as illustrated in FIG. 6. The slowing or termination of the vertical or the Z-direction movement is calculated to maintain the substrate in the plating solution contained in cell 504 when the tilt angle is reduced. Further, embodiments of the invention contemplate that the removal of the tilt angle, i.e., the return of contact ring 302 to a substantially horizontal position, may be conducted simultaneously with the vertical movement of contact ring 302 into the plating solution. As such, embodiments of the invention contemplate that the substrate may first contact the plating solution with the substrate being positioned at a tilt angle, and then the tilt angle may be returned to horizontal while the substrate continues to be immersed into the plating solution. This process generates a unique movement that includes both vertical actuation and tilt angle actuation, which has been shown to reduce bubble formation and adherence to the substrate surface during the immersion process. Further, the vertical and pivotal actuation of the substrate during immersion process may also include rotational movement of contact ring 302, which has been shown to further minimize bubble formation and adherence to the substrate surface during the immersion process.

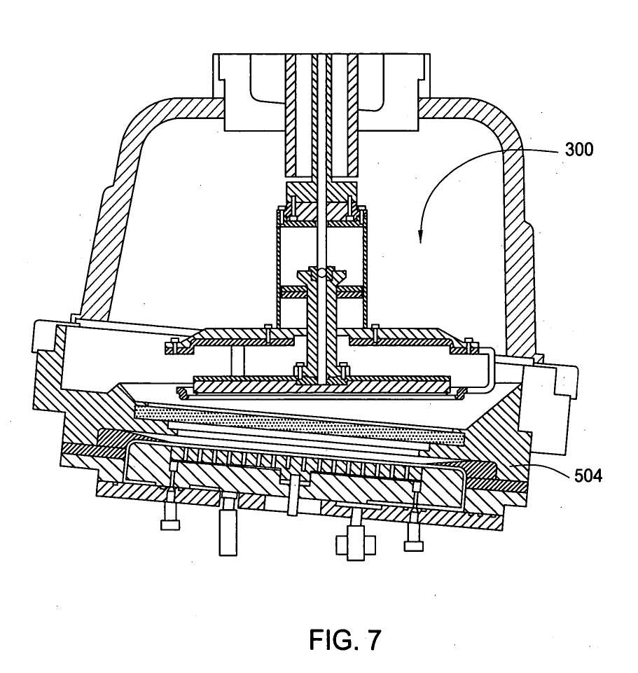

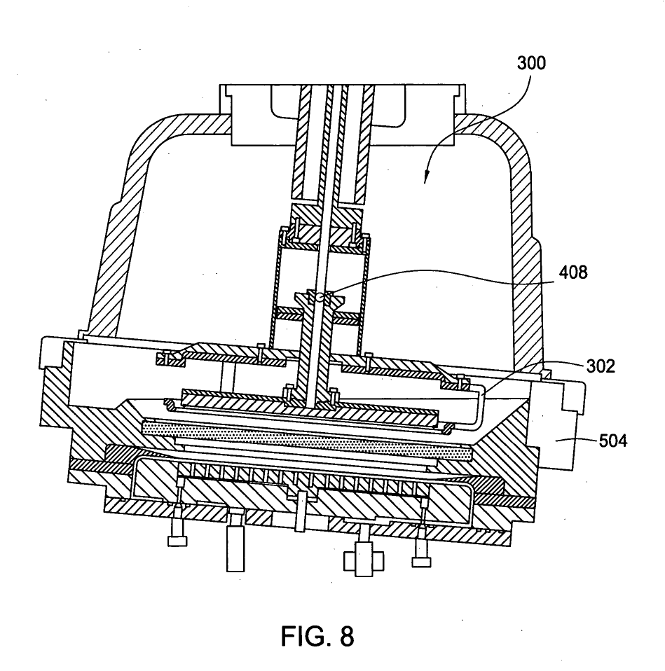

Once the substrate is completely immersed into the plating solution contained within cell 504, head assembly 300 may be further actuated in a vertical direction (downward) to further immerse the substrate into the plating solution, i.e., to position the substrate further or deeper into the plating solution, as illustrated in FIG. 7. This process may also include rotating the substrate, which operates to dislodge any bubbles formed during the immersion process from the substrate surface. Once the substrate is positioned deeper within the plating solution, the head assembly 300 may again be pivoted about pivot point 408, so the substrate surface may be positioned in parallel relationship to the upper surface of the anode 205, as illustrated in FIG. 8.

Although head assembly 300 actuates the substrate downward into the plating solution in the previous step, the tilting motion illustrated in FIG. 8 generally will not raise the surface of the substrate out of the plating solution on the high side of the tilted contact ring. More particularly, since pivot point 408 is positioned in the middle of head assembly 300, when the head assembly pivots the contact ring 302 about pivot point 408, one side of the contact ring 302 is immersed further into the plating solution, while the opposing side of the contact ring 302 is raised upward toward the surface of the plating solution as a result of the pivotal motion. Thus, since the substrate is intended to be maintained within the plating solution once immersed therein, head assembly 300 will generally be actuated further into the plating solution in order to move the contact ring 302 from the horizontal position illustrated in FIG. 7 to the tilted position illustrated in FIG. 8 without raising at least a portion of the substrate out of the plating solution. This final tilting motion of head assembly 300 generally corresponds to positioning contact ring 302 in a processing position, i.e., a position where the substrate supported by contact ring 302 is generally parallel to an anode positioned in a lower portion of the plating cell 502, which generally corresponds to positioning the substrate at a processing angle. The processing angle generally corresponds to the angle that the upper surface of the anode 205 makes with respect to horizontal. Further, positioning contact ring 302 in the processing position may include further actuating head assembly 300 toward the anode positioned in the lower portion of the plating cell, so that the plating surface of the substrate may be positioned at a particular distance from the anode for the plating process.

Additionally, the immersion process of the invention may include an oscillation motion configured to further enhance the bubble removal process. More particularly, head assembly 300 may be tilted back and forth between a first tilt angle and a second tilt angle in an oscillatory manner, i.e., in a manner where the substrate is tilted between a first angle and a second angle several times, once the substrate is immersed in the plating solution. This tilting motion may be conducted in a quick manner, i.e., from about 2 tilts per second up to about 20 tilts per second. The tilting motion may be accompanied by rotation, which further facilitates dislodging bubbles that are adhering to the substrate surface.

The immersion process of the invention may also include vertical oscillation of the substrate in the plating solution. More particularly, once the substrate is immersed in the plating solution, the substrate may be actuated up and down. When the substrate is raised upward in the plating solution, the volume of solution below the substrate is increased, and therefore, a rapid flow of solution to the area below the substrate is generated. Similarly, when the substrate is lowered, the volume decreases and an outward flow of solution is generated. As such, actuation of the substrate vertically, i.e. repeated upward and downward motions, causes reversing or oscillating fluid flows to occur at the substrate surface. The addition of rotation to the oscillation further increases the oscillating fluid flows across the substrate surface. These oscillating fluid flows have been shown to improve bubble removal, and therefore, decrease defects.

The immersion process of the invention may further include oscillating the rotation of the substrate once it is immersed in the plating solution. More particularly, the substrate is generally rotated during both the immersion and plating processes. This rotation generally increases fluid flow at the substrate surface via circulation of the depleted plating solution that is generated at the substrate surface. These rotation and fluid flow characteristics may also be used during the immersion process to facilitate bubble removal. More particularly, embodiments of the invention contemplate that the substrate may be rotated at varying rotation rates and in varying directions during and/or after the substrate is immersed. For example, once the substrate is immersed in the solution, the substrate may first be rotated in a clockwise direction for a predetermined period of time before the rotation direction is switched to counter clockwise for a predetermined period of time. The rotation direction may be switched several times, or only once, depending upon the application.

Additionally, embodiments of the invention may implement a combination of the oscillation methods described above. For example, an immersion process of the invention may include tilt actuation, rotational actuation, and vertical actuation, or any combination thereof.

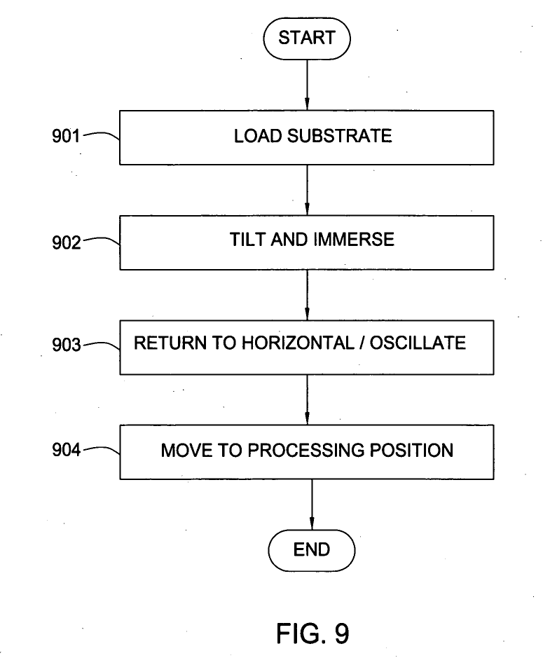

FIG. 9 illustrates a flowchart of the immersion method of the invention. The immersion method begins at step 901, with the substrate to be plated is loaded all into the contact ring 302 of the head assembly 300. The loading process generally includes extending a robot blade into the loading space 306 between the thrust plate 304 and the contact ring 302 to position a substrate on the contact ring 302. Once the substrate is positioned on the contact ring 302, thrust plate 304 may be actuated to secure the substrate to the contact ring for processing.

With the substrate secured to contact ring 302 for processing, the immersion method continues to step 902, where the contact ring is tilted to a tilt angle, rotated, and actuated toward the plating solution contained in the plating cell below. The process of tilting and actuating toward the plating solution may be conducted simultaneously, or alternatively, conducted separately, wherein the tilting portion of the process is conducted first, such that when the contact ring 302 reaches the plating solution the head assembly 300 is already tilted to the tilt angle.

Once the substrate makes contact with the surface of the plating solution contained within the plating cell, the immersion method continues to step 903, where the contact ring 302 is tilted back to horizontal, i.e., the tilt angle is removed. The process of returning the contact ring, and end the substrate positioned thereon, back to a horizontal position may be accomplished in several ways. For example, and as the contact ring and the substrate positioned thereon begins to touch the plating solution, the tilt angle of the contact ring 300 may begin to be decreased or returned back to horizontal. Since the contact ring is still being actuated vertically, i.e. actuated toward the plating solution, the simultaneous decrease in the tilt angle causes the substrate surface to engage the plating solution contained in the plating cell in a vertical manner as a result of the vertical actuation, and in a varying angular manner as a result of the tilt angle being decreased as the vertical movement of the head assembly 300 is continued for the plating solution. Another method of returning the contact ring 302 to the horizontal position, i.e., removing the tilt angle, may include completely immersing the contact ring into the plating solution in with the tilt angle remaining constant. Then, and once the substrate is immersed in the plating solution, the tilt angle may be adjusted back to horizontal. However, regardless of the method used to return the contact ring to the horizontal position, it is important to maintain the substrate immersed in the plating solution, i.e., it is important to make sure that the high side of the contact ring is not tilted out of the plating solution to expose the substrate to the ambient atmosphere, as this is known to cause plating defects. Regardless of the method employed, generally, contact ring 302 is rotated throughout the entire immersion process.

Additionally, embodiments of the invention contemplate expanding step 903 to include multiple tilting motions once the substrate is immersed within the plating solution. For example, once the substrate is immersed in the plating solution, head assembly 300 may operate to tilt contact ring 302 back and forth between a tilt angle in one direction to a tilt angle in another direction. This tilting or pendulum type motion may operate to dislodge bubbles that are adhering to the surface of the substrate as a result of the immersion process. The repeated tilting or pendulum type motion may also include rotation of the substrate, which when combined with the tilting motion, has been shown to substantially remove the amount of bubbles adhering to the substrate surface. Additional oscillatory motions that may be implemented aside from or in conjunction with the tilt oscillation include vertical actuation, rotational actuation, and horizontal actuation.

Once the substrate is immersed in the plating solution and any bubbles adhering to the substrate surface are dislodged therefrom, the immersion method of the invention continues to step 904, where contact ring 302 is actuated into a processing or plating position. The processing or plating position generally includes positioning the substrate such that the substrate surface is parallel to an upper surface of the anode positioned within the plating cell. Further, in addition to being parallel to the anode surface, the substrate may also be positioned a particular distance from the upper surface of the anode, or alternatively, a particular distance from the upper surface of a diffusion member or other member positioned within the plating cell between the substrate and the anode.

In another embodiment of the invention, the immersion process includes the following motions. Once the substrate is loaded into the contact ring 302, i.e., loaded and secured by the thrust plate 304, the substrate and head assembly 300 may be tilted to an angle from horizontal of between about 3° and about 7° and actuated toward the processing solution contained in a processing cell positioned below the head assembly 300. Once the leading edge of the substrate contacts the processing solution, the tilt angle may be reduced. The reduction in the tilt angle may occur simultaneously with a continued actuation of the substrate into the processing solution, or alternatively, once the leading edge is immersed into the solution a predetermined distance, the actuation toward the processing solution may be stopped while the reduction in the tilt angle is continued. The tilt angle is generally reduced until the substrate is once again positioned in a substantially horizontal plane. The entire process of immersing the substrate into the processing solution generally includes rotating the substrate. The rotation speed may be between 30 rpm and about 240 rpm, or more particularly, between about 45 rpm and about 90 rpm.

The process of both actuating the substrate toward the processing solution while simultaneously reducing the tilt angle has been shown to substantially reduce plating defects resulting from bubble adherence to the substrate surface. The inventors have concluded that the combination of the angular motion along with the vertical actuation and rotation of the substrate operates to substantially reduce bubble adherence during the immersion process, and as such, reduces subsequent plating defects. Further, the inventors have determined that positioning the pivot point for the substrate above the substrate provided improved defect reduction results when compared to conventional immersion processes and configurations. More particularly, the inventors have found that improved defect ratios result when the above noted immersion process is conducted, e.g., when the central axis of the substrate is maintained proximate the center of the processing solution bath during the immersion process.

While the foregoing is directed to embodiments of the present invention, other and further embodiments of the invention may be devised without departing from the basic scope thereof, and the scope thereof is determined by the claims that follow.

What is claimed is:

1. A method for immersing a substrate into a fluid solution, comprising:
loading a substrate into a receiving member configured to support the substrate in a face down orientation;
tilting the receiving member to a first tilt angle measured from horizontal;
displacing the receiving member toward the fluid solution at the first tilt angle; and
tilting the receiving member to a second tilt angle measured from horizontal when the substrate contacts the fluid solution, the second tilt angle being different from the first tilt angle.

2. The method of claim 1, wherein the first tilt angle is between about 3° and about 10°.

3. The method of claim 1, wherein the second tilt angle is about 0°.

4. The method of claim 1, further comprising rotating the receiving member at a rotation rate of between about 30 rpm and about 240 rpm.

5. The method of claim 1, further comprising oscillating the second tilt angle once the substrate is immersed in the fluid solution.

6. The method of claim 5, further comprising oscillating the substrate in a vertical direction once the substrate is immersed in the fluid solution.

7. The method of claim 1, further comprising positioning the receiving member such that a plating surface of the substrate is positioned parallel to an upper surface of an anode positioned in the fluid solution once the substrate is immersed in the fluid solution.

8. A method for minimizing bubble adherence during a substrate immersion process, comprising:
tilting the substrate to a tilt angle measured from horizontal;
vertically actuating the substrate toward a fluid solution while maintaining the tilt angle;
reducing the tilt angle to about horizontal once the substrate contacts the fluid solution, while continuing the vertical actuation of the substrate; and
positioning the substrate at a processing angle in the vertical actuating is complete.

9. The method of claim 8, further comprising rotating the substrate at a rate of between about 60 rpm and about 120 rpm.

10. The method of claim 8, further comprising oscillating the tilt angle of the substrate after the substrate is immersed in the fluid solution and before positioning the substrate at the processing angle.

11. The method of claim 8, wherein the processing angle corresponds to an angle that an upper surface of an anode positioned in the fluid solution makes with respect to horizontal.

12. The method of claim 8, wherein the tilt angle is between about 3° and about 7°.

13. The method of claim 8, wherein the tilt angle is reduced to horizontal before the vertical actuation is completed.

14. The method of claim 8, wherein the tilt angle is greater than 0° at a time when the substrate becomes completely immersed in the fluid solution.

15. A method for immersing a substrate into a plating electrolyte, comprising:
positioning the substrate on a contact ring;
securing the substrate to the contact ring with a thrust plate assembly;
tilting the contact ring to a tilt angle of between about 3° and about 7°;
vertically actuating the contact ring toward the plating electrolyte while maintaining the tilt angle;
rotating the contact ring at a rotation rate of between about 30 rpm and about 120 rpm;
reducing the tilt angle to about horizontal when the contact ring initially touches the plating electrolyte; and
positioning the substrate in a processing position.

16. The method of claim 15, further comprising reducing the tilt angle to about horizontal before stopping the vertical actuation.

17. The method of claim 15, wherein positioning the substrate in a processing position comprises positioning the substrate substantially parallel to an upper surface of an anode positioned in the plating electrolyte.

18. The method of claim 17, wherein the upper surface of the anode is tilted from horizontal at an angle of between about 4° and about 10°.

19. The method of claim 18, further comprising oscillating the tilt angle of the substrate after the tilt angle is reduced to about horizontal.

20. The method of claim 15, further comprising maintaining a central axis of the substrate proximate a center of the electrolyte solution during the immersion process.
